(19) United States
(12) Patent Application Publication
(10) Pub. No.: US 2014/0265623 A1
(43) Pub. Date: Sep. 18, 2014

(54) STEP-DOWN CIRCUIT AND POWER RECEIVING DEVICE USING STEP-DOWN CIRCUIT

(71) Applicant: MURATA MANUFACTURING CO., LTD., Nagaokakyo-Shi (JP)

(72) Inventor: KEIICHI ICHIKAWA, Nagaokakyo-shi (JP)

(73) Assignee: MURATA MANUFACTURING CO., LTD., Nagaokakyo-Shi (JP)

(21) Appl. No.: 14/289,196

(22) Filed: May 28, 2014

Related U.S. Application Data
(63) Continuation of application No. PCT/JP2012/075353, filed on Oct. 1, 2012.

(30) Foreign Application Priority Data
Dec. 1, 2011 (JP) 2011-264076

(51) Int. Cl. H01L 41/04; H02J 17/00; H01L 41/107

(52) U.S. Cl. CPC H01L 41/044; H01L 41/107; H02J 17/00
USPC 307/104; 310/318; 323/355

(57) ABSTRACT

A step-down circuit using a piezoelectric transformer that includes a rectangular parallelepiped piezoelectric plate having opposite end portions in a lengthwise direction thereof, which are constituted as two lower voltage portions provided with output electrodes, and a region sandwiched between the two lower voltage portions. The region being partly constituted as a higher voltage portion provided with an input electrode. The two lower voltage portions and the higher voltage portion are each polarized and driven in a 3/2λ or a 5/2λ mode. The higher voltage portion or vicinities thereof are polarized in directions symmetric to each other on both the sides of a center of the higher voltage portion or on both the sides of the higher voltage portion. The output electrodes on the positive and negative charge sides of respective polarized lower voltage portions are connected to each other.

### CROSS-REFERENCE TO RELATED APPLICATIONS

The present application is a continuation of PCT/JP2012/075353 filed Oct. 1, 2012, which claims priority to Japanese Patent Application No. 2011-264076, filed Dec. 1, 2011, the entire contents of each of which are incorporated herein by reference.

### FIELD OF THE INVENTION

The present invention relates to a step-down circuit, which has a simple structure and a lower height, and which can perform unbalance-balance conversion and voltage step-down at the same time, and further relates to a power receiving device using the step-down circuit.

### BACKGROUND OF THE INVENTION

Various types of electronic equipment for transferring electric power in a non-contact manner have been developed in recent years. To transfer electric power with the electronic equipment in a non-contact manner, a power transfer system of magnetic field coupling type including coil modules in both a power transmitting unit and a power receiving unit is employed in many cases.

In the magnetic field coupling type system, a magnitude of magnetic flux passing through each coil module greatly affects electromotive force. Accordingly, a relative positional relation in a coil plane direction between the coil module in the power transmitting unit side (primary side) and the coil module in the power receiving unit side (secondary side) is important to realize high power transfer efficiency. Furthermore, because the coil modules are used as coupling electrodes, it is difficult to reduce the sizes and the thicknesses of the power transmitting unit and the power receiving unit.

In view of the above-described situation, a power transfer system of electric field coupling type, for example, is developed. Patent Document 1 discloses an energy carrying device that realizes high power-transfer efficiency by forming a strong electric field between a coupling electrode in the power transmitting unit side and a coupling electrode in the power receiving unit side. FIG. 21 is a schematic view illustrating the configuration of a power transfer system of related art. As illustrated in FIG. 21, the power transfer system of related art includes a larger-sized passive electrode 3 and a smaller-sized active electrode 4 in a power transmitting unit (power transmitting device) 1, and a larger-sized passive electrode 5 and a smaller-sized active electrode 6 in a power receiving unit (power receiving device) 2. High power-transfer efficiency is realized by forming a strong electric field 7 between the active electrode 4 in the power transmitting unit 1 and the active electrode 6 in the power receiving unit 2.

In the power transfer system of electric field coupling type, the magnitude of transferred power, the transfer efficiency, etc. depend on the intensity of coupling between the electrodes. To intensify the coupling between the electrodes, it is required to shorten the distance between the electrodes, or to increase areas of the electrodes. FIG. 22 is an equivalent circuit diagram illustrating the configuration of the power transfer system of related art. As illustrated in FIG. 22, in order to transfer electric power through a coupling capacity CM, a step-up circuit 13 is required in the power transmitting unit 1, and a step-down circuit 20 is required in the power receiving unit 2. Usually, the transfer efficiency is increased by employing a resonance circuit that exhibits a small power loss. A lower voltage is generated in the larger-sized passive electrode 5 in the power receiving unit 2, and a higher voltage is generated in the smaller-sized active electrode 6 therein. A coupling electrode in the power receiving unit 2 is constituted by the passive electrode 5 and the active electrode 6. Therefore, an asymmetric voltage (i.e., a voltage regarded to be unbalanced because of being close to a reference potential) is supplied to the step-down circuit 20, and a voltage stepped down by the step-down circuit 20 is supplied to a load circuit RL.

Preferably, the step-down circuit 20 is small and thin as far as possible for the reason that the step-down circuit 20 is assembled in the power receiving unit 2, which undergoes strict physical limitations such as in size of a casing.

Because the step-down circuit 20 has a structure including coils wound around a magnetic substance as illustrated in FIG. 22, it is difficult to realize not only reduction in size and thickness, but also a decrease of loss and an increase of breakdown voltage at the same time.

The step-down circuit 20 illustrated in FIG. 22 is a step-down circuit of unbalanced-unbalanced type, and it corresponds to the case where the load circuit RL is of unbalanced type. On the other hand, when the output side of the step-down circuit is connected to a bridge rectifier circuit (which is of balanced input type), a step-down circuit of unbalanced-balanced type is constituted.

FIG. 23 illustrates an example of the step-down circuit 20 constituted by a related-art wiring transformer and having the unbalance-balance conversion function. In FIG. 23, unbalanced input terminals of the step-down circuit 20 are connected to power receiving electrodes (power supply circuit). Balanced output terminals of the step-down circuit 20 are connected to balanced input terminals of a load circuit. By constituting the step-down circuit 20 to be the unbalance-balance conversion type, when the load circuit is of balanced input type, the step-down circuit 20 and the load circuit can be connected to each other with no need of the unbalance-balance conversion. The step-down circuit 20 of unbalance-balance conversion type illustrated in FIG. 23 also has a structure including coils wound around a magnetic substance. It is hence difficult to realize not only reduction in size and thickness, but also a decrease of loss and an increase of breakdown voltage at the same time.

In view of the above-described situation, studies have been made on use of, e.g., a piezoelectric device (piezoelectric transformer) in the step-down circuit 20. FIG. 24 is a perspective view illustrating the configuration of a related-art piezoelectric transformer utilizing a 3/2λ mode (tertiary), and FIG. 25 is a perspective view illustrating the configuration of a related-art piezoelectric transformer utilizing a 1/2λ mode (primary) and 2/2λ mode (secondary). As illustrated in FIGS. 24 and 25, a related-art piezoelectric transformer 23 includes a piezoelectric plate 200 having a rectangular parallelepiped shape.

As illustrated in FIG. 24(a), in the related-art piezoelectric transformer 23 utilizing 3/2λ mode, input electrodes 201A and 201B and input electrodes 202A and 202B, each having a planar shape, are disposed as driving portions on upper and lower surfaces of both end portions of the piezoelectric plate 200, and both the end portions of the piezoelectric plate 200 are each polarized in the direction of thickness of the piezoelectric plate 200. Furthermore, output electrodes 203A and 203B are disposed as power generating portions on upper and lower surfaces of a central portion of the piezoelectric plate 200 in the lengthwise direction thereof, and the central portion of the piezoelectric plate 200 is polarized in the lengthwise direction of the piezoelectric plate 200.

The piezoelectric transformer 23 illustrated in FIG. 24(a) vibrates as illustrated in FIG. 24(b). In more detail, the so-called node points (support points) where a displacement of the vibration is 0 (zero) are generated substantially at a center of the piezoelectric plate 200 in the lengthwise direction thereof and at positions spaced from the center toward both ends thereof by about λ/2. A maximum displacement is generated at both the ends of the piezoelectric plate 200 and at positions spaced from both the ends toward the center by about λ/2. A portion between the input electrodes 201A and 201B, and a portion between the input electrodes 202A and 202B in both the end portions are connected in parallel to take out an output current. When an input voltage is applied between the input electrodes 201A and 201B and between the input electrodes 202A and 202B, a high stepped-up voltage can be taken out from the output electrodes 203A and 203B by the actions of the piezoelectric effect and the inverse piezoelectric effect.

On the other hand, in the piezoelectric transformer 23 utilizing the 1/2λ mode and the 2/2λ mode, illustrated in FIG. 25, a rectangular parallelepiped piezoelectric plate, denoted by 210, is employed as in the piezoelectric transformer 23 utilizing the 3/2λ mode, illustrated in FIG. 24, but the modes are differently generated depending on the position of the node point (support point).

As illustrated in FIG. 25(a), the piezoelectric plate 210 is divided into a first region and a second region in the lengthwise direction thereof. Planar input electrodes 211A and 211B are disposed as driving portions on upper and lower surfaces of the first region, and the first region is polarized in the direction of thickness of the piezoelectric plate 210. Furthermore, an output electrode 213 is disposed as a power generating portion on an end surface of the second region, and the second region is polarized in the lengthwise direction of the piezoelectric plate 210.

In vibration of the piezoelectric transformer 23 utilizing the 1/2λ mode, as illustrated in FIG. 25(b), the so-called node point where a displacement of the vibration is 0 (zero) is generated substantially at a center of the piezoelectric plate 210 in the lengthwise direction thereof, and a maximum displacement is generated at both ends of the piezoelectric plate 210.

Furthermore, in vibration of the piezoelectric transformer 23 utilizing the 2/2λ mode, the so-called node points where a displacement of the vibration is 0 (zero) are generated at positions spaced by about λ/4 from substantially the center of the piezoelectric plate 210 toward both the ends in the lengthwise direction thereof, and a maximum displacement is generated at both the ends of the piezoelectric plate 210 and at a position (i.e., at substantially the center) spaced by about λ/2 from the both ends toward the center. When an input voltage is applied between the input electrodes 211A and 211B, a high stepped-up voltage can be taken out from the output electrode 213 by the actions of the piezoelectric effect and the inverse piezoelectric effect.

The piezoelectric transformers 23 utilizing the 3/2λ mode, the 1/2λ mode, and the 2/2λ mode, described above, are each of unbalanced-unbalanced type. FIG. 26 is a schematic view illustrating the configuration of a power transfer circuit, which employs an unbalance-balance conversion circuit constituted by the related-art piezoelectric transformer 23 utilizing the 3/2λ mode, the 1/2λ mode, or the 2/2λ mode.

As illustrated in FIG. 26, electrodes on the higher voltage sides of a first piezoelectric transformer element and a second piezoelectric transformer element, each utilizing the 1/2λ, mode or the 2/2λ mode, are connected to an unbalanced terminal. An output electrode on the positive charge side of one polarized lower voltage portion of the first piezoelectric transformer element and an output electrode on the negative charge side of the other polarized lower voltage portion are connected to each other through a midpoint. An output electrode on the negative charge side of the one polarized lower voltage portion and an output electrode on the positive charge side of the other polarized lower voltage portion are used as balanced output terminals. The midpoint is grounded. With the connection described above, the difference in amplitude with respect an input voltage between an output voltage of the first piezoelectric transformer element and an output voltage of the second piezoelectric transformer element is held substantially 0 (zero), and balanced output voltages having a phase difference of 180 degrees can be obtained.

Thus, because plural piezoelectric transformer elements are required, the size of the step-down circuit 20 is increased. Furthermore, due to variations in resonance frequencies of the plural piezoelectric transformer elements, positional deviations of the piezoelectric transformer elements from the node points (support points), and so on, the difference in amplitude with respect the input voltage between the output voltage of the first piezoelectric transformer element and the output voltage of the second piezoelectric transformer element is increased and the phase difference is departed from 180 degrees. This causes the problem that a degree of balancing degrades and power transfer efficiency reduces. An unbalance-balance conversion circuit can be similarly constituted by the piezoelectric transformer 23 utilizing the 3/2λ mode, but the above-described problem is not overcome.
Patent Document 1: Japanese Unexamined Patent Application Publication (Translation of PCT application) No. 2009-531009

When the step-down circuit 20 is constituted by employing the piezoelectric transformer 23, two piezoelectric transformer elements have to be used and the two piezoelectric transformer elements have to be connected to the ground potential in common in order to realize the unbalance-balance conversion. Because of employing the plural piezoelectric transformer elements, the resonance frequency cannot be uniquely determined, and power reception characteristics are not stabilized. Even in the case of employing the piezoelectric transformer 23, therefore, it has been difficult to reduce the size and the thickness of the step-down circuit 20, and to stabilize the power reception characteristics.

### SUMMARY OF THE INVENTION

The present invention has been accomplished in view of the above-described situations, and an object of the present invention is to provide a step-down circuit capable of reducing the size and the thickness thereof while realizing the unbalance-balance conversion, and to provide a power receiving device using the step-down circuit.

To achieve the above object, the present invention provides a step-down circuit using a piezoelectric transformer including a rectangular parallelepiped piezoelectric plate, the piezoelectric plate having opposite end portions in a lengthwise direction thereof, which are constituted as two lower voltage portions provided with output electrodes, and a region sandwiched between the two lower voltage portions, the region being partly constituted as a higher voltage portion provided with an input electrodes, the two lower voltage portions and the higher voltage portion being each polarized and driven in a 3/2λ or a 5/2λ mode, wherein the higher voltage portion or vicinities of the higher voltage portion are polarized in directions symmetric to each other on both sides of a center of the higher voltage portion or on both sides of the higher voltage portion, the output electrode on a positive charge side of one of the polarized lower voltage portions and the output electrode on a negative charge side of the other polarized lower voltage portion are connected to each other, and the step-down circuit includes a balanced output electrode on a negative charge side of the one polarized lower voltage portion and a balanced output electrode on a positive charge side of the other polarized lower voltage portion.

With the features described above, since the piezoelectric transformer has a symmetric structure sandwiching the higher voltage portion between the two lower voltage portions and is driven with a vibration mode set to the 3/2λ or the 5/2λ mode, the piezoelectric transformer can be supported at the nodes of the vibration mode, or the input electrode and the output electrodes can be arranged at the nodes. Accordingly, adverse effects on mounted portions, such as stress and distortion caused by the vibration, can be reduced. Furthermore, since the unbalance-balance conversion can be performed with one piezoelectric transformer, it is easier to reduce the size and the thickness of the step-down circuit. In addition, a transformation ratio can be easily increased by forming the piezoelectric transformer in a multilayer structure.

In the step-down circuit according to the present invention, preferably, an inductor is connected between the balanced output electrode on the negative charge side of the one polarized lower voltage portion and the balanced output electrode on the positive charge side of the other polarized lower voltage portion.

With the feature described above, impedance matching between the step-down circuit and the load circuit can be improved, and power transfer efficiency can be increased.

In the step-down circuit according to the present invention, preferably, the two lower voltage portions are polarized in a direction perpendicular to the lengthwise direction of the piezoelectric plate, and the higher voltage portion or the vicinities of the higher voltage portion are polarized in the lengthwise direction of the piezoelectric plate.

With the features described above, since the lower voltage portions are polarized in the direction perpendicular to the lengthwise direction of the piezoelectric plate and the higher voltage portion (in the case of 3/2λ mode) or the vicinities of the higher voltage portion (in the case of 5/2λ mode) are polarized in the lengthwise direction of the piezoelectric plate, the vibration mode can be set to a higher-order mode, i.e., the 3/2λ mode or the 5/2λ mode, and the input electrode and the output electrodes can be easily arranged at the nodes of the vibration mode.

In the step-down circuit according to the present invention, preferably, the two lower voltage portions are polarized in directions perpendicular to the lengthwise direction of the piezoelectric plate and opposite to each other.

With the feature described above, since the two lower voltage portions are polarized in directions perpendicular to the lengthwise direction of the piezoelectric plate and opposite to each other, wiring layout can be simplified when the output electrode on the positive charge side of one of the polarized lower voltage portions and the output electrode on the negative charge side of the other polarized lower voltage portion are connected to each other. Hence, further reduction in size and thickness can be realized as a whole.

To achieve the above object, the present invention further provides a power receiving device in which the power receiving device includes a second passive electrode and a second active electrode, the second active electrode and a first active electrode of a power transmitting device are positioned to face each other with a gap left therebetween while the second passive electrode and a first passive electrode of the power transmitting device are positioned to face each other such that the second and first electrodes are capacitively coupled to each other, and electric power is transferred in a noncontact manner by forming a stronger electric field between the first active electrode and the second active electrode than between the first passive electrode and the second passive electrode, wherein the power receiving device includes one of the above-described step-down circuits, and a load circuit of a balanced input type to which a balanced output voltage of the step-down circuit is input.

With the features described above, since the step-down circuit is constituted by employing the piezoelectric transformer that has the symmetric structure sandwiching the higher voltage portion between the two lower voltage portions and that is driven with a vibration mode set to the 3/2λ or a 5/2λ mode, the piezoelectric transformer can be supported at nodes of the vibration mode, or the input electrode and the output electrodes can be arranged at the nodes. Accordingly, adverse effects on mounted portions, such as stress and distortion caused by the vibration, can be reduced. Furthermore, since the unbalance-balance conversion can be performed with one piezoelectric transformer, it is easier to reduce the size and the thickness of the step-down circuit. In addition, since a transformation ratio can be easily increased by forming the piezoelectric transformer in a multilayer structure, the power receiving device having high power-transfer efficiency even with a small size can be provided.

In the power receiving device according to the present invention, preferably, the load circuit includes a rectifier circuit to which the balanced output voltage of the step-down circuit is input.

With the features described above, since the load circuit includes the rectifier circuit to which the balanced output voltage of the step-down circuit is input, stable electric power can be supplied to the load circuit. Therefore, the power receiving device can be operated, for example, to function as a charging device for an electronic device.

With the step-down circuit and the power receiving device using the step-down circuit, according to the present invention, since the step-down circuit is constituted by employing the piezoelectric transformer that has the symmetric structure sandwiching the higher voltage portion between the two lower voltage portions and that is driven with a vibration mode set to the 3/2λ or a 5/2λ mode, the piezoelectric transformer can be supported at nodes of the vibration mode, or the input electrode and the output electrodes can be arranged at the nodes. Accordingly, adverse effects on mounted portions, such as stress and distortion caused by the vibration, can be reduced. Furthermore, since the unbalance-balance conversion can be performed with one piezoelectric transformer, it is easier to reduce the size and the thickness of the step-down circuit. In addition, since a transformation ratio can be easily increased by forming the piezoelectric transformer in a multilayer structure, the power receiving device having high power transfer efficiency even with a small size can be provided.

### BRIEF DESCRIPTION OF DRAWINGS

FIG. 1 is a perspective view illustrating the configuration of a piezoelectric transformer of 5/2λ mode type, which is used in a step-down circuit according to Embodiment 1 of the present invention.

FIG. 2 is a schematic sectional view taken along a plane perpendicular to the lengthwise direction of the piezoelectric transformer, the view illustrating the configurations of output electrodes that are formed in a lower voltage portion of the piezoelectric transformer according to Embodiment 1 of the present invention.

FIG. 3 is a schematic sectional view taken along a plane perpendicular to the lengthwise direction of the piezoelectric transformer, the view illustrating the configurations of input electrodes that are formed in a higher voltage portion of the piezoelectric transformer according to Embodiment 1 of the present invention.

FIG. 4 is a schematic view illustrating a polarized state of the piezoelectric transformer according to Embodiment 1 of the present invention.

FIG. 5 is a schematic view illustrating the configuration of the step-down circuit according to Embodiment 1 of the present invention.

FIG. 6 is a schematic view illustrating the configuration of a power transfer circuit using the step-down circuit according to Embodiment 1 of the present invention when a rectifier circuit is employed.

FIG. 7 is a schematic view illustrating the configuration of the power transfer circuit using the step-down circuit according to Embodiment 1 of the present invention when a full-wave rectifier circuit is employed.

FIG. 8 is a schematic view illustrating a polarized state of a piezoelectric transformer according to Embodiment 2 of the present invention.

FIG. 9 is a schematic view illustrating the configuration of a step-down circuit according to Embodiment 2 of the present invention.

FIG. 10 is a perspective view illustrating the configuration of a piezoelectric transformer of 5/2λ mode type, which is used in a step-down circuit according to Embodiment 3 of the present invention.

FIG. 11 is a schematic sectional view taken along a horizontal plane extending in the widthwise direction of the piezoelectric transformer, the view illustrating the configurations of output electrodes that are formed in one lower voltage portion of the piezoelectric transformer according to Embodiment 3 of the present invention.

FIG. 12 is a schematic sectional view taken along a horizontal plane extending in the widthwise direction of the piezoelectric transformer, the view illustrating the configurations of the output electrodes that is formed in the other lower voltage portion of the piezoelectric transformer according to Embodiment 3 of the present invention.

FIG. 13 is a schematic sectional view taken along a horizontal plane extending in the widthwise direction of the piezoelectric transformer, the view illustrating the configurations of input electrodes that are formed in a higher voltage portion of the piezoelectric transformer according to Embodiment 3 of the present invention.

FIG. 14 is a schematic view illustrating a polarized state of the piezoelectric transformer according to Embodiment 3 of the present invention.

FIG. 15 is a schematic view illustrating the configuration of a step-down circuit according to Embodiment 3 of the present invention.

FIG. 16 is a set of schematic views illustrating the polarized states and wiring layouts of the piezoelectric transformers according to Embodiments 1 to 3 of the present invention.

FIG. 17 is a set of other schematic views illustrating the polarized states and the wiring layouts of the piezoelectric transformers according to Embodiments 1 to 3 of the present invention.

FIG. 18 is a perspective view illustrating the configuration of a piezoelectric transformer of 3/2λ mode type, which is used in a step-down circuit according to Embodiment 4 of the present invention.

FIG. 19 is a set of schematic views illustrating polarized states and wiring layouts of the piezoelectric transformer according to Embodiment 4 of the present invention.

FIG. 20 is a set of other schematic views illustrating the polarized states and the wiring layouts of the piezoelectric transformer according to Embodiment 4 of the present invention.

FIG. 21 is a schematic view illustrating the configuration of a power transfer system of related art.

FIG. 22 is an equivalent circuit diagram illustrating the configuration of the power transfer system of related art.

FIG. 23 illustrates an example of a step-down circuit of related art, which is constituted by a winding transformer and which has the unbalance-balance conversion function.

FIG. 24 is a perspective view illustrating the configuration of a related-art piezoelectric transformer utilizing a 3/2λ mode (tertiary).

FIG. 25 is a perspective view illustrating the configuration of a related-art piezoelectric transformer utilizing a 1/2λ mode (primary) and a 2/2λ mode (secondary).

FIG. 26 is a schematic view illustrating the configuration of a power transfer circuit using an unbalance-balance conversion circuit, which is constituted by related-art piezoelectric transformers utilizing the 3/2λ mode, the 1/2λ mode, or the 2/2λ mode.

### DETAILED DESCRIPTION OF THE PREFERRED EMBODIMENTS

Step-down circuits according to embodiments of the present invention, and power receiving devices using the step-down circuits will be described in detail below with reference to the drawings. It is a matter of course that the following embodiments are not intended to limit the invention defined in Claims, and that all of combinations of feature matters described in the embodiments are not always essential matters for solution to the problems.

### Embodiment 1

FIG. 1 is a perspective view illustrating the configuration of a piezoelectric transformer of 5/2λ mode type, which is used in a step-down circuit according to Embodiment 1 of the present invention. As illustrated in FIG. 1, a piezoelectric transformer 23 according to Embodiment 1 is formed of a piezoelectric plate 31 that is a piezoelectric ceramic multilayer plate having a rectangular parallelepiped shape with a thickness T, a width W, and a length L. Opposite end portions of the piezoelectric plate 31 are lower voltage portions L1 and L5 each exhibiting a comparatively low voltage, and a central portion of the piezoelectric plate 31 is a higher voltage portion L3 exhibiting a comparatively high voltage. The piezoelectric transformer 23 is a piezoelectric transformer having a symmetric structure and driven in the 5/2λ mode. Output electrodes 34a and 34b are formed in one lower voltage portion L5 of the piezoelectric transformer 23, input electrodes 33a and 33b are formed in the higher voltage portion L3, and output electrodes 32a and 32b are formed in the other lower voltage portion L1, respectively.

A PZT (lead zirconate titanate: PbZrO₃—PbTiO₃)-based piezoelectric ceramic is used as a material of the piezoelectric plate 31. The output electrodes 32a, 32b, 34a, and 34b and the input electrodes 33a and 33b are each formed by screen-printing an Ag paste and firing the Ag paste.

FIG. 2 is a schematic sectional view taken along a plane perpendicular to the lengthwise direction of the piezoelectric transformer 23, the view illustrating the configurations of the output electrodes 32a (34a) and 32b (34b) that are formed in the lower voltage portions L1 and L5 of the piezoelectric transformer 23 according to Embodiment 1 of the present invention.

As illustrated in FIG. 2, the piezoelectric plate 31 of the piezoelectric transformer 23 according to Embodiment 1 is made up of plural electrode layers that are stacked in a direction perpendicular to the lengthwise direction of the piezoelectric plate 31. The electrode layers are alternately connected to the output electrode 32a (34a) or the output electrode 32b (34b), which are formed on both lateral sides of the piezoelectric plate 31, respectively. The lower voltage portions L1 and L5 are polarized in the direction of the thickness T of the piezoelectric plate 31 (i.e., in the direction perpendicular to the lengthwise direction of the piezoelectric plate 31). Because an even number of electrode layers are stacked in the example of FIG. 2, the polarization direction is alternately reversed between the adjacent layers. For the sake of easier understanding, the polarization direction in the entirety of each lower voltage portion L1 or L5 is denoted in a different way using an empty arrow.

FIG. 3 is a schematic sectional view taken along a plane perpendicular to the lengthwise direction of the piezoelectric transformer 23, the view illustrating the configurations of the input electrodes 33a and 33b that are formed in the higher voltage portion L3 of the piezoelectric transformer 23 according to Embodiment 1 of the present invention.

As illustrated in FIG. 3, in the higher voltage portion L3 of the piezoelectric transformer 23 according to Embodiment 1 of the present invention, plural electrode layers are stacked in the direction perpendicular to the lengthwise direction of the piezoelectric plate 31. The input electrode 33a and the input electrode 33b formed on both the lateral sides of the piezoelectric plate 31 are short-circuited in each layer. Poling is performed between each of the input electrode 33a and the input electrode 33b and each of the output electrode 32a (34a) and the output electrode 32b (34b), whereby a polarized portion L2 and a polarized portion L4 are formed. Stated another way, a plurality of electrode layers is disposed in the higher voltage portion L3 including the boundary between the polarized portion L2 and the higher voltage portion L3 and the boundary between the polarized portion L4 and the higher voltage portion L3. In FIG. 1, the output electrode 32a (34a), the output electrode 32b (34b), the input electrode 33a, and the input electrode 33b are denoted by hatching. In the subsequent drawings, the hatching is omitted as appropriate. The electrode cross-section illustrated in FIG. 3 is desirably formed in the vicinities of a boundary surface between the polarized portion L2 and the higher voltage portion L3 and a boundary surface between the higher voltage portion L3 and the polarized portion L4. Vibration is suppressed by forming the inner electrodes in an entire region of the higher voltage portion L3.

FIG. 4 is a schematic view illustrating a polarized state of the piezoelectric transformer 23 according to Embodiment 1 of the present invention. As illustrated in FIG. 4, the lower voltage portions L1 and L5 are polarized in the direction of the thickness T of the piezoelectric plate 31 (i.e., in the direction perpendicular to the lengthwise direction of the piezoelectric plate 31) and further in the same direction. The polarized portions L2 and L4 (in the vicinities of the higher voltage portion L3) sandwiching the higher voltage portion L3 are polarized in the lengthwise of the piezoelectric plate 31 and further in directions symmetric to each other on both the sides of the higher voltage portion L3 interposed therebetween. Thus, in both the end portions of the piezoelectric transformer 23 according to Embodiment 1, the direction of vibration caused by deformation and the polarization direction are orthogonal to each other. The electrode layers in the higher voltage portion L3 are short-circuited to provide a not-polarized region.

By employing the piezoelectric transformer 23 having the above-described configuration, a step-down circuit is constituted as follows. FIG. 5 is a schematic view illustrating the configuration of the step-down circuit according to Embodiment 1 of the present invention.

As illustrated in FIG. 5, an input signal source (AC) is connected between each of the input electrodes 33a and 33b of the piezoelectric transformer 23 and the ground potential. The output electrode 34a and the output electrode 32b of the piezoelectric transformer 23 are connected to the ground potential, and output-side wiring lines are connected to the output electrodes 32a and 34b. In other words, the step-down circuit is featured in connecting the output electrode 34a on the positive charge side of the one polarized lower voltage portion L5 to the output electrode 32b on the negative charge side of the other polarized lower voltage portion L1, and further connecting both the output electrode 34a and 32b to the ground such that those output electrodes are successively connected along the polarization direction.

In Embodiment 1, the piezoelectric transformer 23 having a symmetric structure and driven in the 5/2λ mode is employed, and the input electrode 33a and 33b formed in the higher voltage portion L3 of the piezoelectric transformer 23 are unbalanced input terminals. Moreover, the output electrode 34a and the output electrode 32b are connected to each other and grounded such that those output electrodes are successively connected along the polarization direction. With the above-described connection, the remaining output electrodes 34b and 32a are constituted as balanced output terminals (balanced output electrodes), which exhibit an amplitude difference of substantially 0 between respective output voltages of the output electrode 34b and the output electrode 32a with respect to an input voltage, and which output balanced output voltages having a phase difference of 180 degrees. The balanced output terminals are connected to balanced input terminals (balanced input electrodes) of a load circuit R. An inductor 50 for impedance matching is connected in parallel to the balanced input terminals of the load circuit R, i.e., between the balanced output terminals. With the connection of the inductor 50, electric power can be efficiently supplied to the load circuit R from the piezoelectric transformer 23.

When an input voltage Vin is applied, it is stepped down by the piezoelectric transformer 23, and an output voltage Vout lower than the input voltage Vin is output. Since the output voltage Vout is output to the balanced output terminals, the unbalance-balance conversion can be performed at the same time as the step-down.

A drive frequency is determined depending on the vibration mode and the device size of the piezoelectric transformer 23. In the case of the piezoelectric transformer 23 having the symmetric structure and driven in the 5/2λ mode, for example, the drive frequency is set near the resonance frequency and it is about 50 kHz to 1 MHz. An inductance value of the external inductor 50 is set in match with the output impedance of the piezoelectric transformer 23.

According to Embodiment 1, as described above, since it is no longer required to connect a plurality of windings unlike the case using a winding transformer, the size and the thickness of the step-down circuit can be reduced. Furthermore, since the piezoelectric transformer 23 can be wired or supported at the nodes of vibration, a step-down circuit can be provided which can reduce a risk of the occurrence of failures, such as disconnection and breakage, caused by the vibration, and which can exhibit stable characteristics. In addition, by increasing the number of multiple layers stacked in the piezoelectric transformer 23, a transformation ratio (step-down ratio) can be easily increased.

FIG. 6 is a schematic view illustrating the configuration of a power transfer circuit using the step-down circuit according to Embodiment 1 of the present invention when a rectifier circuit is employed. In FIG. 6, the step-down circuit according to Embodiment 1 is included in a power receiving device 2.

A power transmitting device 1 includes at least a power source 12, a step-up circuit (not illustrate), and a first coupling electrode 11 that is constituted by a first active electrode 11a and a first passive electrode 11p. On the other hand, a power receiving device 2 includes a second coupling electrode 12 that is constituted by a second active electrode 21a and a second passive electrode 21p, a step-down circuit using the piezoelectric transformer 23 according to Embodiment 1, an inductor 50, a rectifier circuit 60, and a load circuit R.

The first coupling electrode 21 of the power transmitting device 1 and the second coupling electrode 11 of the power receiving device 2 are capacitively coupled to each other through a capacitance CM such that electric power output from the power source 12 of the power transmitting device 1 is transferred to the power receiving device 2. The electric power received by the second coupling electrode 21 is stepped down by the step-down circuit, rectified by the rectifier circuit 60 of bridge type including a plurality of diodes after passing the inductor 50, and is then input to the load circuit R. It is to be noted that a load circuit including the rectifier circuit 60 of bridge type is called the load circuit R of balanced input type hereinafter.

The piezoelectric transformer 23 is the piezoelectric transformer having the symmetric structure and driven in the 5/2λ mode, and the electric power received by the second coupling electrode 21 is supplied to the input electrodes 33a and 33b, which are formed in the higher voltage portion L3 of the piezoelectric transformer 23. Moreover, the output electrode 34a on the positive charge side of the one polarized lower voltage portion L5 and the output electrode 32b on the negative charge side of the other polarized lower voltage portion L1 are connected to each other and grounded such that those output electrodes are successively connected along the polarization direction. The remaining output electrodes 34b and 32a supply the balanced output voltage to the load circuit R of balanced input type.

By constituting the power transfer circuit as described above, it is possible to reduce the size and the thickness of the power receiving device 2, and to provide the power receiving device 2 having stable power reception characteristics because the resonance frequency can be uniquely determined with no need of employing a plurality of piezoelectric transformer elements unlike the related art.

A rectifier circuit is not limited to the above-described rectifier circuit 60 of bridge type, and the rectifier circuit may be a full-wave rectifier circuit, for example. FIG. 7 is a schematic view illustrating the configuration of the power transfer circuit using the step-down circuit according to Embodiment 1 of the present invention when the full-wave rectifier circuit is employed.

The power transfer circuit illustrated in FIG. 7 has the same configuration as that illustrated in FIG. 6 except for the rectifier circuit. Therefore, other corresponding components of the power transfer circuit are denoted by the same reference signs, and detailed description of those components is omitted. The electric power received by the second coupling electrode 21 is stepped down by the step-down circuit, rectified by a full-wave rectifier circuit 61 including a plurality of diodes after passing the inductor 50, and is then input to the load circuit R.

In the case using the full-wave rectifier circuit 61, the number of diodes is reduced by half in comparison with the case using the bridge-type rectifier circuit 60, i.e., from four to two. Accordingly, the size and the thickness of the power receiving device 2 can be further reduced.

### Embodiment 2

A piezoelectric transformer of 5/2λ mode type used in a step-down circuit according to Embodiment 2 has a similar configuration to that in Embodiment 1. Therefore, corresponding components of the power transfer circuit are denoted by the same reference signs, and detailed description of those components is omitted. Embodiment 2 is different from Embodiment 1 in that the lower voltage portions L1 and L5 are polarized in the direction of the thickness T of the piezoelectric plate 31 (i.e., in the direction perpendicular to the lengthwise direction of the piezoelectric plate 31) and further in directions opposite to each other. FIG. 8 is a schematic view illustrating a polarized state of the piezoelectric transformer 23 according to Embodiment 2 of the present invention.

As illustrated in FIG. 8, the lower voltage portions L1 and L5 are polarized in the direction of the thickness T of the piezoelectric plate 31 and further in directions opposite to each other. The polarized portions L2 and L4 (in the vicinities of the higher voltage portion L3) sandwiching the higher voltage portion L3 are polarized in the lengthwise of the piezoelectric plate 31 and further in directions symmetric to each other on both the sides of the higher voltage portion L3 interposed therebetween. Thus, in both the end portions of the piezoelectric transformer 23 according to Embodiment 2, the direction of vibration caused by deformation and the polarization direction are orthogonal to each other as in Embodiment 1.

By employing the piezoelectric transformer 23 having the above-described configuration, a step-down circuit is constituted as follows. FIG. 9 is a schematic view illustrating the configuration of the step-down circuit according to Embodiment 2 of the present invention.

As illustrated in FIG. 9, a constant current source is disposed on the input side. One end of the constant current source is grounded, and the other end of the constant current source is connected to the input electrodes 33a and 33b of the piezoelectric transformer 23. The output electrode 34b and the output electrode 32b of the piezoelectric transformer 23 are connected to the ground potential, and output-side wiring lines are connected to the output electrodes 32a and 34a. In other words, the step-down circuit is featured in connecting the output electrode 34b on the positive charge side of the one polarized lower voltage portion L5 to the output electrode 32b on the negative charge side of the other polarized lower voltage portion L1, and further connecting both the output electrodes 34b and 32b to the ground such that those output electrodes are successively connected along the polarization direction.

Also in Embodiment 2, the piezoelectric transformer 23 having a symmetric structure and driven in the 5/2λ mode is employed, and the input electrodes 33a and 33b formed in the higher voltage portion L3 of the piezoelectric transformer 23 are unbalanced input terminals. Moreover, the output electrode 34b and the output electrode 32b are connected to each other and grounded such that those output electrodes are successively connected along the polarization direction. The remaining output electrode 34a and 32a are connected as balanced output terminals to the load circuit R. An inductor 50 is connected in parallel to the load circuit R, i.e., between the balanced output terminals. In Embodiment 2, ground lines do not intersect each other and wiring layout is more simplified. As a result, further reduction in size and thickness can be realized in the entirety of the step-down circuit.

According to Embodiment 2, as described above, the size and the thickness of the step-down circuit can be reduced in comparison with the case using a winding transformer. Furthermore, since the piezoelectric transformer 23 can be wired or supported at the nodes of vibration mode, a step-down circuit can be provided which can reduce a risk of the occurrence of failures, such as disconnection and breakage, caused by the vibration, and which can exhibit stable characteristics. In addition, the wiring layout can be further simplified, thus contributing to further reduction in cost of the entire manufacturing process.

Moreover, by constituting the power transfer circuit as described above, it is possible to reduce the size and the thickness of the power receiving device 2, and to provide the power receiving device 2 having stable power reception characteristics because the resonance frequency can be uniquely determined with no need of employing a plurality of piezoelectric transformer elements.

### Embodiment 3

A piezoelectric transformer of 5/2λ mode type used in a step-down circuit according to Embodiment 3 of the present invention has a similar configuration to those in Embodiments 1 and 2. Therefore, corresponding components of the power transfer circuit are denoted by the same reference signs, and detailed description of these components is omitted. Embodiment 3 is different from Embodiments 1 and 2 in that the lower voltage portions L1 and L5 are polarized in the lengthwise direction of the piezoelectric plate 31.

FIG. 10 is a perspective view illustrating the configuration of the piezoelectric transformer 23 of 5/2λ mode type, which is used in a step-down circuit according to Embodiment 3 of the present invention. As illustrated in FIG. 10, the piezoelectric transformer 23 according to Embodiment 3 is formed of a piezoelectric plate 31 that is a piezoelectric ceramic multilayer plate having a rectangular parallelepiped shape with a thickness T, a width W, and a length L. Opposite end portions of the piezoelectric plate 31 are lower voltage portions L1 and L5 each exhibiting a comparatively low voltage, and a central portion of the piezoelectric plate 31 is a higher voltage portion L3 exhibiting a comparatively high voltage. The piezoelectric transformer 23 is a piezoelectric transformer having a symmetric structure and driven in the 5/2λ mode. Output electrodes 34a and 34b are formed in one lower voltage portion L5 of the piezoelectric transformer 23, input electrodes 33a and 33b are formed in the higher voltage portion L3, and output electrodes 32a and 32b are formed in the other lower voltage portion L1, respectively.

FIG. 11 is a schematic sectional view taken along a horizontal plane extending in the widthwise direction W of the piezoelectric transformer 23, the view illustrating the configurations of the output electrodes 32a and 32b that are formed in the lower voltage portion L1 of the piezoelectric transformer 23 according to Embodiment 3 of the present invention. FIG. 12 is a schematic sectional view taken along a horizontal plane extending in the widthwise direction W of the piezoelectric transformer 23, the view illustrating the configurations of the output electrodes 34a and 34b that are formed in the lower voltage portion L5 of the piezoelectric transformer 23 according to Embodiment 3 of the present invention.

As illustrated in FIG. 11, the piezoelectric plate 31 of the piezoelectric transformer 23 according to Embodiment 3 is made up of plural electrode layers that are stacked in the lengthwise direction of the piezoelectric plate 31. The electrode layers are alternately connected to the output electrode 32a and the output electrode 32b, which are formed on both lateral sides of the piezoelectric plate 31, respectively. The lower voltage portion L1 is polarized in the lengthwise direction of the piezoelectric plate 31. Because an even number of electrode layers are stacked in the example of FIG. 11, the polarization direction is alternately reversed between the adjacent layers. For the sake of easier understanding, the polarization direction in the entire lower voltage portion L1 is denoted in a different way using an empty arrow.

In FIG. 12, similarly, the piezoelectric plate 31 is made up of plural electrode layers that are stacked in the lengthwise direction of the piezoelectric plate 31. The electrode layers are alternately connected to the output electrode 34a and the output electrode 34b, which are formed on both the lateral sides of the piezoelectric plate 31, respectively. The lower voltage portion L5 is also polarized in the lengthwise direction of the piezoelectric plate 31. Because an even number of electrode layers are stacked in the example of FIG. 12, the polarization direction is alternately reversed between the adjacent layers. For the sake of easier understanding, the polarization direction in the entire lower voltage portion L5 is denoted in a different way using an empty arrow.

FIG. 13 is a schematic sectional view taken along a horizontal plane extending in the direction of the width W of the piezoelectric transformer 23, the view illustrating the configurations of the input electrodes 33a and 33b that are formed in the higher voltage portion L3 of the piezoelectric transformer 23 according to Embodiment 3 of the present invention.

As illustrated in FIG. 13, no electrodes layers are stacked in the higher voltage portion L3 of the piezoelectric transformer 23 according to Embodiment 3, and the input electrode 33a and the input electrode 33b are short-circuited. In other words, the input electrode 33a and the input electrode 33b are disposed at positions including the boundary between the polarized portion L2 and the higher voltage portion L3 and the boundary between the polarized portion L4 and the higher voltage portion L3.

FIG. 14 is a schematic view illustrating a polarized state of the piezoelectric transformer 23 according to Embodiment 3 of the present invention. As illustrated in FIG. 14, the lower voltage portions L1 and L5 are polarized in the lengthwise direction of the piezoelectric plate 31 and further in directions opposite to each other. The polarized portions L2 and L4 (in the vicinities of the higher voltage portion L3) sandwiching the higher voltage portion 13 are polarized in the lengthwise of the piezoelectric plate 31 and further in directions symmetric to each other on both the sides of the higher voltage portion 13 interposed therebetween. Thus, in both the end portions of the piezoelectric transformer 23 according to Embodiment 3, the direction of vibration caused by deformation and the polarization direction are the same.

By employing the piezoelectric transformer 23 having the above-described configuration, a step-down circuit is constituted as follows. FIG. 15 is a schematic view illustrating the configuration of the step-down circuit according to Embodiment 3 of the present invention.

As illustrated in FIG. 15, an input signal source (AC) is connected between each of the input electrodes 33a and 33b of the piezoelectric transformer 23 and the ground potential. The output electrode 34a and the output electrode 32b of the piezoelectric transformer 23 are connected to the ground potential, and output-side wiring lines are connected to the output electrodes 32a and 34b. In other words, the step-down circuit is featured in connecting the output electrode 34a on the positive charge side of the one polarized lower voltage portion L5 to the output electrode 32b on the negative charge side of the other polarized lower voltage portion L1, and further connecting both the output electrodes 34a and 32b to the ground such that those output electrodes are successively connected along the polarization direction.

In Embodiment 3, the piezoelectric transformer 23 having a symmetric structure and driven in the 5/2λ mode is employed, and the input electrodes 33a and 33b formed in the higher voltage portion L3 of the piezoelectric transformer 23 are unbalanced input terminals. Moreover, the output electrode 34a and the output electrode 32b are connected to each other and grounded such that those output electrodes are successively connected along the polarization direction. The remaining output electrodes 34b and 32a are connected as balanced output terminals to the load circuit R. An inductor 50 is connected in parallel to the load circuit R, i.e., between the balanced output terminals. With the connection of the inductor 50, electric power can be efficiently supplied to the load circuit R from the piezoelectric transformer 23.

When an input voltage Vin is applied, it is stepped down by the piezoelectric transformer 23, and an output voltage Vout lower than the input voltage Vin is output. Since the output voltage Vout is output to the balanced output terminals to which the inductor 50 is connected, the unbalance-balance conversion can be performed at the same time as the step-down.

A drive frequency is determined depending on the vibration mode and the device size of the piezoelectric transformer 23. In the case of the piezoelectric transformer 23 having the symmetric structure and driven in the 5/2λ mode, for example, the drive frequency is set near the resonance frequency and it is about 50 kHz to 1 MHz. An inductance value of the external inductor 50 is set in match with the output impedance of the piezoelectric transformer 23.

According to Embodiment 3, as described above, since it is no longer required to connect a plurality of windings unlike the case using a winding transformer, the size and the thickness of the step-down circuit can be reduced. Furthermore, since the piezoelectric transformer 23 can be wired or supported at the nodes of vibration, a step-down circuit can be provided which can reduce a risk of the occurrence of failures, such as disconnection and breakage, caused by the vibration, and which can exhibit stable characteristics. In addition, by increasing the number of multiple layers stacked in the piezoelectric transformer 23, a transformation ratio (step-down ratio) can be easily increased. Since the polarization directions of the lower voltage portions L1 and L5 in both the end portions are set to be the same as the direction of vibration, an effective electromechanical coupling coefficient can be increased, and hence higher efficiency can be realized.

As in Embodiments 1 and 2, by employing the step-down circuit according to Embodiment 3, it is possible to reduce the size and the thickness of the power receiving device 2, and to provide the power receiving device 2 having stable power reception characteristics because the resonance frequency can be uniquely determined with no need of employing a plurality of piezoelectric transformer elements.

It is to be noted that the polarization direction of the piezoelectric transformer 23 is not limited to the direction described in each of Embodiments 1 to 3, similar advantageous effects can also be expected insofar as the vicinities of the higher voltage portion L3 are polarized in directions symmetric to each other on both the sides of the higher voltage portion L3 interposed therebetween. FIG. 16 is a set of schematic views illustrating the polarized states and the wiring layouts of the piezoelectric transformers 23 according to Embodiments 1 to 3 of the present invention. In FIG. 16, G denotes a ground terminal, A and B denote balanced output terminals, and H denotes an input terminal.

FIG. 16(a) represents the polarized state and the wiring layout of the piezoelectric transformer 23 according to Embodiment 1. Although FIG. 16(a) is illustrated in such a manner that the connection to the ground potential is reversed in the right-and-left direction from the case illustrated in FIGS. 5 to 7, the arrangements of FIG. 16(a) and FIGS. 5 to 7 are substantially the same. In FIG. 16(a), the input terminal H is connected to the input electrodes 33a and 33b of the higher voltage portion L3. Furthermore, the ground terminal G is connected to the output electrode 32a, and the output electrodes 32a and 34b are connected such that those output electrodes are successively connected along the polarization direction. The balanced output terminal A is connected to the output electrode 32b, and the balanced output terminal B is connected to the output electrode 34a. The step-down circuit is thus formed.

Similarly, FIG. 16(b) represents the polarized state and the wiring layout of the piezoelectric transformer 23 according to Embodiment 3. Although FIG. 16(b) is illustrated in such a manner that the connection to the ground potential is reversed in the right-and-left direction from the case illustrated in FIG. 15, the arrangements of FIG. 16(b) and FIG. 15 are substantially the same. In FIG. 16(b), the input terminal H is connected to the input electrodes 33a and 33b of the higher voltage portion L3. Furthermore, the ground terminal G is connected to the output electrode 32a, and the output electrodes 32a and 34b are connected such that those output electrodes are successively connected along the polarization direction. The balanced output terminal A is connected to the output electrode 32b, and the balanced output terminal B is connected to the output electrode 34a. The step-down circuit is thus formed.

While, in FIGS. 16(c) and 16(d), the individual terminals and electrodes are connected similarly to the above-described cases, FIGS. 16(c) and 16(d) are different from FIGS. 16(a) and 16(b) in the polarization direction, respectively. In FIG. 16(c), the lower voltage portions L1 and L5 are polarized in the direction of the thickness T of the piezoelectric plate 31 and further in the same direction. The polarized portions L2 and L4 sandwiching the higher voltage portion L3 are polarized in the direction of the thickness T and further in directions symmetric to each other on both the sides of the higher voltage portion L3 interposed therebetween.

In FIG. 16(d), the lower voltage portions L1 and L5 are polarized in the lengthwise direction of the piezoelectric plate 31 and further in directions opposite to each other. The polarized portions L2 and L4 sandwiching the higher voltage portion L3 are polarized in the direction of the thickness T of the piezoelectric plate 31 and further in directions symmetric to each other.

The configuration to simplify the wiring layout is also conceivable as in Embodiment 2. FIG. 17 is a set of other schematic views illustrating the polarized states and the wiring layouts of the piezoelectric transformers 23 according to Embodiments 1 to 3 of the present invention. Also in FIG. 17, G denotes a ground terminal, A and B denote balanced output terminals, and H denotes an input terminal.

FIG. 17(a) represents the polarized state and the wiring layout of the piezoelectric transformer 23 according to Embodiment 2. Although FIG. 17(a) is illustrated in such a manner that the connection to the ground potential is reversed in the right-and-left direction from the case illustrated in FIG. 9, the arrangements of FIG. 17(a) and FIG. 9 are substantially the same. In FIG. 17(a), the input terminal H is connected to the input electrodes 33a and 33b of the higher voltage portion L3. Furthermore, the ground terminal G is connected to the output electrode 32b, and the output electrodes 32b and 34b are connected such that those output electrodes are successively connected along the polarization direction. The balanced output terminal A is connected to the output electrode 32a, and the balanced output terminal B is connected to the output electrode 34a. The step-down circuit is thus formed.

While, in FIGS. 17(b), 17(c) and 17(d), the individual terminals and electrodes are connected similarly to the above-described case, FIGS. 17(b), 17(c) and 17(d) are different from FIG. 17(a) in the polarization direction. More specifically, in FIG. 17(b), the lower voltage portions L1 and L5 are polarized in the lengthwise direction of the piezoelectric plate 31 and further in the same direction. The polarized portions L2 and L4 sandwiching the higher voltage portion L3 are polarized in the lengthwise direction of the piezoelectric plate 31 and further in directions opposite to each other on both the sides of the higher voltage portion L3 interposed therebetween.

In FIG. 17(c), the lower voltage portions L1 and L5 are polarized in the direction of the thickness T of the piezoelectric plate 31 and further in directions opposite to each other. The polarized portions L2 and L4 sandwiching the higher voltage portion L3 are polarized in the direction of the thickness T of the piezoelectric plate 31 and further in directions symmetric to each other on both the sides of the higher voltage portion L3 interposed therebetween.

In FIG. 17(d), the lower voltage portions L1 and L5 are polarized in the lengthwise direction of the piezoelectric plate 31 and further in the same direction. The polarized portions L2 and L4 sandwiching the higher voltage portion L3 are polarized in the direction of the thickness T of the piezoelectric plate 31 and further in directions symmetric to each other on both the sides of the higher voltage portion 13 interposed therebetween.

By connecting wiring lines in each of the piezoelectric transformers 23 polarized as described above and employing each of the piezoelectric transformers in the step-down circuit, it is possible to reduce the size and the thickness of the step-down circuit, and hence to reduce the size and the thickness of the power receiving device 2.

### Embodiment 4

FIG. 18 is a perspective view illustrating the configuration of s piezoelectric transformer of 3/2λ mode type (Rosen tertiary type), which is used in a step-down circuit according to Embodiment 4 of the present invention. As illustrated in FIG. 18, the piezoelectric transformer 23 according to Embodiment 4 is formed of a piezoelectric plate 31 that is a piezoelectric ceramic multilayer plate having a rectangular parallelepiped shape with a thickness T, a width W, and a length L. Opposite end portions of the piezoelectric plate 31 are lower voltage portions L6 and L8 each exhibiting a comparatively low voltage, and a central portion of the piezoelectric plate 31 is a higher voltage portion L7 exhibiting a comparatively high voltage. The piezoelectric transformer 23 is a piezoelectric transformer having a symmetric structure and driven in the 3/2λ mode. Output electrodes 34a and 34b are formed in one lower voltage portion L8 of the piezoelectric transformer 23, input electrodes 33a and 33b are formed in the higher voltage portion L7, and output electrodes 32a and 32b are formed in the other lower voltage portion L6, respectively.

FIG. 19 is a set of schematic views illustrating the polarized states and the wiring layouts of the piezoelectric transformer 23 according to Embodiment 4 of the present invention. In FIG. 19, G denotes a ground terminal, A and B denote balanced output terminals, and H denotes an input terminal.

As illustrated in FIG. 19(a), the lower voltage portions L6 and L8 are polarized in the direction of the thickness T of the piezoelectric plate 31 (i.e., in the direction perpendicular to the lengthwise direction of the piezoelectric plate 31) and further in the same direction. The higher voltage portion L7 is polarized in the lengthwise direction of the piezoelectric plate 31 and further in directions symmetric to each other on both the sides of a center of the higher voltage portion L7. Thus, in both the end portions of the piezoelectric transformer 23 according to Embodiment 4, the direction of vibration caused by deformation and the polarization direction are orthogonal to each other.

Furthermore, the input terminal H is connected to the input electrodes 33a and 33b of the higher voltage portion L7. The ground terminal G is connected to the output electrode 32a, and the output electrodes 32a and 34b are connected such that those output electrodes are successively connected along the polarization direction. The balanced output terminal A is connected to the output electrode 32b, and the balanced output terminal B is connected to the output electrode 34a. The step-down circuit is thus formed.

The polarization direction of the piezoelectric transformer 23 is not limited to that illustrated in FIG. 19(a). It is just required that, as in Embodiments 1 to 3, the higher voltage portion L7 is polarized in directions symmetric to each other on both the sides of a center of the higher voltage portion L7.

While, in FIGS. 19(b), 19(c) and 19(d) representing other examples, the individual terminals and electrodes are connected similarly to the above-described case, FIGS. 19(b), 19(c) and 19(d) are different from FIG. 19(a) in the polarization direction. More specifically, in FIG. 19(b), the lower voltage portions L6 and L8 are polarized in the lengthwise direction of the piezoelectric plate 31 and further in directions opposite to each other. The higher voltage portion L7 is polarized in the lengthwise direction of the piezoelectric plate 31 and further in directions symmetric to each other on both the sides of the center of the higher voltage portion L7.

In FIG. 19(c), the lower voltage portions L6 and L8 are polarized in the direction of the thickness T of the piezoelectric plate 31 and further in the same direction. The higher voltage portion L7 is polarized in the direction of the thickness T of the piezoelectric plate 31 and further in directions symmetric to each other on both the sides of the center of the higher voltage portion L7.

In FIG. 19(d), the lower voltage portions L6 and L8 are polarized in the lengthwise direction of the piezoelectric plate 31 and further in directions opposite to each other. The higher voltage portion L7 is polarized in the direction of the thickness T of the piezoelectric plate 31 and further in directions symmetric to each other on both the sides of the center of the higher voltage portion L7.

In the piezoelectric transformer 23 of the 3/2λ mode, the configuration to simplify the wiring layout is also conceivable as in Embodiment 2. FIG. 20 is a set of other schematic views illustrating the polarized states and the wiring layouts of the piezoelectric transformers 23 according to Embodiment 4 of the present invention. Also in FIG. 20, G denotes a ground terminal, A and B denote balanced output terminals, and H denotes an input terminal.

In FIG. 20(a), the input terminal H is connected to the input electrodes 33a and 33b of the higher voltage portion L7. Furthermore, the ground terminal G is connected to the output electrode 32b, and the output electrodes 32b and 34b are connected such that those output electrodes are successively connected along the polarization direction. The balanced output terminal A is connected to the output electrode 32a, and the balanced output terminal B is connected to the output electrode 34a. The step-down circuit is thus formed.

While, in FIGS. 20(b), 20(c) and 20(d), the individual terminals and electrodes are connected similarly to the above-described case, FIGS. 20(b), 20(c) and 20(d) are different from FIG. 20(a) in the polarization direction. More specifically, in FIG. 20(b), the lower voltage portions L6 and L8 are polarized in the lengthwise direction of the piezoelectric plate 31 and further in the same direction. The higher voltage portion L7 is polarized in the lengthwise direction of the piezoelectric plate 31 and further in directions symmetric to each other on both the sides of the center of the higher voltage portion L7.

In FIG. 20(c), the lower voltage portions L6 and L8 are polarized in the direction of the thickness T of the piezoelectric plate 31 and further in directions opposite to each other. The higher voltage portion L7 is polarized in the direction of the thickness T of the piezoelectric plate 31 and further in directions symmetric to each other on both the sides of the center of the higher voltage portion L7.

In FIG. 20(d), the lower voltage portions L6 and L8 are polarized in the lengthwise direction of the piezoelectric plate 31 and further in the same direction. The higher voltage portion L7 is polarized in the direction of the thickness T of the piezoelectric plate 31 and further in directions symmetric to each other on both the sides of the center of the higher voltage portion L7.

By connecting wiring lines in each of the piezoelectric transformers 23 polarized as described above and employing each of the piezoelectric transformers in the step-down circuit, it is possible to reduce the size and the thickness of the step-down circuit, and hence to reduce the size and the thickness of the power receiving device 2.

It is needless to say that the present invention is not limited to the above-described embodiments, and that various modifications, substitutions, etc. can be made within the scope not departing from the gist of the present invention.

### REFERENCE SIGNS LIST

1 power transmitting device
2 power receiving device
11a first active electrode
11p first passive electrode
12 power source
21a second active electrode
21p second passive electrode
23 piezoelectric transformer
31 piezoelectric plate
32a, 32b, 34a, 34b output electrodes
33a, 33b input electrodes
50 inductor
L1, L5, L6, L8 lower voltage portions
L3, L7 higher voltage portions

1. A piezoelectric transformer comprising:
a rectangular parallelepiped piezoelectric plate including:
first and second opposing end portions in a lengthwise direction of the piezoelectric plate, each end portion having a pair of output electrodes, and
an inner region disposed between the first and second end portions, the inner region having an input electrode,
wherein the first and second opposing end portions and the inner region are each polarized and configured to be driven in a 3/2λ or a 5/2λ mode, wherein λ is the wave length of a vibration mode of the piezoelectric transformer, and
wherein the inner region is symmetrically polarized on both sides of a center of the inner region or regions adjacent to the inner region are polarized in directions symmetric to each other on both sides of the inner region.

2. The piezoelectric transformer according to claim 1, wherein the first and second opposing end portions are polarized in a direction perpendicular to the lengthwise direction of the piezoelectric plate.

3. The piezoelectric transformer according to claim 2, wherein the inner region or the regions adjacent to the inner region are polarized in the lengthwise direction of the piezoelectric plate.

4. The piezoelectric transformer according to claim 3, wherein the first and second opposing end portions are polarized in directions opposite to each other.

5. The piezoelectric transformer according to claim 1, wherein the first and second opposing end portions have a first voltage potential and the inner region has a second voltage potential higher than the first voltage potential.

6. The piezoelectric transformer according to claim 1,
wherein each of the first and second opposing end portions comprise a plurality of electrode layers stacked in a direction perpendicular to a lengthwise direction of the piezoelectric plate, and
wherein the plurality of electrode layers are alternatively connected to the pair of output electrodes.

7. A step down circuit comprising:
a piezoelectric transforming having a rectangular parallelepiped piezoelectric plate that includes:
first and second opposing end portions in a lengthwise direction of the piezoelectric plate, each end portion having a pair of output electrodes, and
an inner region disposed between the first and second end portions, the inner region having an input electrode,
wherein the first and second opposing end portions and the inner region are each polarized and configured to be driven in a 3/2λ or a 5/2λ mode, wherein λ is the wave length of a vibration mode of the piezoelectric transformer,
wherein the inner region is symmetrically polarized on both sides of a center of the inner region or regions adjacent to the inner region are polarized in directions symmetric to each other on both sides of the inner region,
wherein the output electrode on a positive charge side of the first end portion and the output electrode on a negative charge side of the second end portion are electrically coupled to each other, and
wherein the output electrode on a negative charge side of the first end portion and the output electrode on a positive charge side of the second end portion comprise a pair of balanced output terminals.

8. The step-down circuit according to claim 7, wherein an inductor is coupled to the pair of balanced output terminals.

9. The step-down circuit according to claim 7, wherein the first and second opposing end portions are polarized in a direction perpendicular to the lengthwise direction of the piezoelectric plate.

10. The step-down circuit according to claim 9, wherein the inner region or the regions adjacent to the inner region are polarized in the lengthwise direction of the piezoelectric plate.

11. The step-down circuit according to claim 10, wherein the first and second opposing end portions are polarized in directions opposite to each other.

12. The step-down circuit according to claim 7, wherein the input electrode of the inner region is coupled to each other as unbalanced input terminals.

13. The step-down circuit according to claim 7, wherein the first and second opposing end portions have a first voltage potential and the inner region has a second voltage potential higher than the first voltage potential.

14. A power receiving device configured to receive power from a power transmitting device when positioned on the power transmitting device; the power receiving device comprising:
a passive electrode and an active electrode configured to face a passive electrode and an active electrode of the power transmitting device such that the respective electrodes are capacitively coupled to each other,
a step down circuit including:
a piezoelectric transforming having a rectangular parallelepiped piezoelectric plate that includes:
first and second opposing end portions in a lengthwise direction of the piezoelectric plate, each end portion having a pair of output electrodes, and
an inner region disposed between the first and second end portions, the inner region having an input electrode,
wherein the first and second opposing end portions and the inner region are each polarized and configured to be driven in a 3/2λ or a 5/2λ mode, wherein λ is the wave length of a vibration mode of the piezoelectric transformer,
wherein the inner region is symmetrically polarized on both sides of a center of the inner region or regions adjacent to the inner region are polarized in directions symmetric to each other on both sides of the inner region,
wherein the output electrode on a positive charge side of the first end portion and the output electrode on a negative charge side of the second end portion are electrically coupled to each other, and
wherein the output electrode on a negative charge side of the first end portion and the output electrode on a positive charge side of the second end portion comprise a pair of balanced output terminals; and
a load circuit coupled to the pair of balanced output terminal.

15. The power receiving device according to claim 14, wherein the load circuit includes a rectifier circuit coupled to the balanced output terminals.

16. The power receiving device according to claim 15, wherein an inductor is coupled in parallel to the pair of balanced output terminals.

17. The power receiving device according to claim 15, wherein the first and second opposing end portions are polarized in a direction perpendicular to the lengthwise direction of the piezoelectric plate.

18. The power receiving device according to claim 17, wherein the inner region or the regions adjacent to the inner region are polarized in the lengthwise direction of the piezoelectric plate.

19. The power receiving device according to claim 18, wherein the first and second opposing end portions are polarized in directions opposite to each other.

20. The power receiving device according to claim 14, wherein the first and second opposing end portions have a first voltage potential and the inner region has a second voltage potential higher than the first voltage potential.
